(19) United States
(12) Patent Application Publication
(10) Pub. No.: US 2026/0214858 A1
(43) Pub. Date: Jul. 23, 2026

(54) HEAT SINK MODULE AND NETWORK SWITCH

(71) Applicant: ACCTON TECHNOLOGY CORPORATION, Hsinchu City (TW)

(72) Inventor: Ting Jui CHANG, Hsinchu City (TW)

(21) Appl. No.: 19/356,220

(22) Filed: Oct. 13, 2025

(30) Foreign Application Priority Data
Jan. 20, 2025 (TW) 114200797

(51) Int. Cl. H05K 7/20; H05K 7/14

(52) U.S. Cl. CPC H05K 7/20509; H05K 7/1461; H05K 7/20409; H05K 7/20445

(57) ABSTRACT

A heat sink module includes a first connecting bracket, a second connecting bracket and a heat dissipation body. The second connecting bracket has at least partial elasticity along a direction. An end of the heat dissipation body is connected with the first connecting bracket along the direction. Another end of the heat dissipation body is connected with the second connecting bracket along the direction.

### RELATED APPLICATIONS

This application claims priority to Taiwanese Application Serial Number 114200797, filed January 20, 2025, which is herein incorporated by reference in its entirety.

### BACKGROUND

### Technical Field

The present disclosure relates to heat sink modules and network switches equipped with these heat sink modules. More particularly, the present disclosure relates to heat sink modules applied to structure of a vertical line card (VLC).

### Description of Related Art

As people's living standards continue to rise, the application of electronic devices has become increasingly widespread. In response to the enormous demand for electronic devices, major manufacturers focus on strengthening the market competitiveness of their brands.

In response to the development of the Internet, the demand for higher transmission speeds in network devices has been rapidly increasing. For example, network switches need to provide faster transmission rates. In practice, network switches include line cards, which are equipped with connectors and slot structures to facilitate the connection of Direct Attach Cables (DAC), enabling data transmission with other network devices. The slot structure is designed to guide and house the DAC, allowing the network switch to communicate with other devices for data transfer. However, with the growing demand for high-speed transmission, DACs generate significant heat, necessitating the use of a heat dissipation module to dissipate this heat. As the assembly methods of line cards vary, the structure and assembly of the heat dissipation module have become critical issues of significant concern for manufacturers.

### SUMMARY

A technical aspect of the present disclosure is to provide a heat sink module, which can be installed on the line card without processing to the line card.

According to an embodiment of the present disclosure, a heat sink module includes a first connecting bracket, a second connecting bracket and a heat dissipation body. The second connecting bracket has at least partial elasticity along a direction. An end of the heat dissipation body is connected with the first connecting bracket along the direction. Another end of the heat dissipation body is connected with the second connecting bracket along the direction.

In one or more embodiments of the present disclosure, the heat dissipation body includes at least one heat conducting duct. The heat conducting duct has a first end and a second end opposite to the first end. The second connecting bracket includes a first body and at least one connecting piece. The first body has at least one through hole. The connecting piece is located in the through hole and elastically connected with the first body along the direction. The connecting piece is connected with the second end.

In one or more embodiments of the present disclosure, the second connecting bracket further includes a protruding annulus. The protruding annulus is disposed inside the through hole. The connecting piece further includes a sleeve, a snapping portion, a connecting portion and an elastic element. The sleeve is slidably disposed in the through hole along the direction. The sleeve accommodates the second end. The snapping portion is configured to abut against the protruding annulus. The connecting portion is connected between the sleeve and the snapping portion along the direction. An end of the elastic element abuts against the protruding annulus. Another end of the elastic element abuts against the sleeve.

In one or more embodiments of the present disclosure, the sleeve and the snapping portion are located at opposite sides of the protruding annulus.

In one or more embodiments of the present disclosure, the second connecting bracket further includes a first positioning portion. The first positioning portion is connected with an edge of the first body. The first positioning portion forms a first included angle together with a surface of the first body away from the first connecting bracket. The first connecting bracket includes a second body and a second positioning portion. The second body is configured to connect with the first end. The second positioning portion is connected with an edge of the second body. The second positioning portion forms a second included angle together with a surface of the second body away from the second connecting bracket.

In one or more embodiments of the present disclosure, the first included angle and the second included angle are respectively a right angle.

A technical aspect of the present disclosure is to provide a network switch, which can allow the heat sink module to be installed on the line card without processing to the line card.

According to an embodiment of the present disclosure, a network switch includes a machine body, a line card and a heat sink module. The machine body includes a main board. The main board is disposed at a bottom of the machine body. The line card includes a printed circuit board, a slot structure, and a plurality of connectors. The printed circuit board is disposed on the machine body. The printed circuit board is perpendicular to the main board. The slot structure includes a first subsidiary slot structure and a second subsidiary slot structure respectively connected with the printed circuit board. The first subsidiary slot structure and the second subsidiary slot structure respectively have a plurality of openings. The connectors are disposed on the printed circuit board and aligned with the openings. The heat sink is sandwiched between the first subsidiary slot structure and the second subsidiary slot structure along a direction. The heat sink module includes a heat dissipation body, a first connecting bracket and a second connecting bracket. The first connecting bracket is connected with a side of the heat dissipation body along the direction and configured to abut against the first subsidiary slot structure. The second connecting bracket is connected with another side of the heat dissipation body along the direction and configured to abut against the second subsidiary slot structure. The second connecting bracket has elasticity along the direction.

In one or more embodiments of the present disclosure, the heat dissipation body includes at least one heat conducting duct. The heat conducting duct has a first end and a second end opposite to the first end. The second connecting bracket includes a first body and at least one connecting piece. The first body has at least one through hole. The connecting piece is located in the through hole and elastically connected with the first body along the direction. The connecting piece is connected with the second end.

In one or more embodiments of the present disclosure, the second connecting bracket further includes a protruding annulus. The protruding annulus is disposed inside the through hole. The connecting piece further includes a sleeve, a snapping portion, a connecting portion and an elastic element. The sleeve is slidably disposed in the through hole along the direction. The sleeve accommodates the second end. The snapping portion is configured to abut against the protruding annulus. The connecting portion is connected between the sleeve and the snapping portion along the direction. An end of the elastic element abuts against the protruding annulus. Another end of the elastic element abuts against the sleeve.

In one or more embodiments of the present disclosure, the sleeve and the snapping portion are located at opposite sides of the protruding annulus.

In one or more embodiments of the present disclosure, the second connecting bracket further includes a first positioning portion. The first positioning portion is connected with an edge of the first body. The first positioning portion forms a first included angle together with a surface of the first body away from the first connecting bracket. The first positioning portion is configured to abut against the second subsidiary slot structure. The first connecting bracket includes a second body and a second positioning portion. The second body is configured to connect with the first end. The second positioning portion is connected with an edge of the second body. The second positioning portion forms a second included angle together with a surface of the second body away from the second connecting bracket. The second positioning portion is configured to abut against the first subsidiary slot structure.

In one or more embodiments of the present disclosure, the first included angle and the second included angle are respectively a right angle.

In one or more embodiments of the present disclosure, the first subsidiary slot structure and the second subsidiary slot structure are integrally formed.

In one or more embodiments of the present disclosure, the heat sink module exerts an elastic force against the first subsidiary slot structure and the second subsidiary slot structure along the direction.

In one or more embodiments of the present disclosure, the heat sink module and the printed circuit board are spaced apart from each other.

In one or more embodiments of the present disclosure, the network switch further includes at least one thermal pad. The thermal pad is sandwiched between the heat sink module and one of the first subsidiary slot structure and the second subsidiary slot structure.

The above-mentioned embodiments of the present disclosure have at least the following advantages:

(1) Since the heat sink module is supported elastically between the subsidiary slot structures, no additional processing is needed to add fastening components to secure the heat sink module. Hence, apart from a saving of labor cost, the structural strength of the line card is maintained.

(2) Since the heat sink module is supported elastically between the subsidiary slot structures, even if there is a relatively large tolerance range in the distance between the subsidiary slot structures, the heat sink module can still be disposed between the subsidiary slot structures of the line card, which effectively enhances the application flexibility of the heat sink module.

(3) Since the heat sink module is supported elastically between the subsidiary slot structures, the installation and removal of the heat sink module can be completed easily and quickly.

### BRIEF DESCRIPTION OF THE DRAWINGS

The disclosure can be more fully understood by reading the following detailed description of the embodiments, with reference made to the accompanying drawings as follows:

FIGS. 1-2 are schematic views of a network switch according to an embodiment of the present disclosure, in which the housing is omitted in FIG. 2;

FIG. 3 is a front view of the network switch of FIG. 2;

FIG. 4 is a top view of the network switch of FIG. 2;

FIG. 5 is a partial sectional view along the sectional line A-A of FIG. 2;

FIG. 6 is a schematic view of the heat sink module of FIGS. 2-4;

FIG. 7 is a sectional view along the sectional line B-B of FIG. 6; and

FIG. 8 is an enlarged view of the zone M of FIG. 7.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

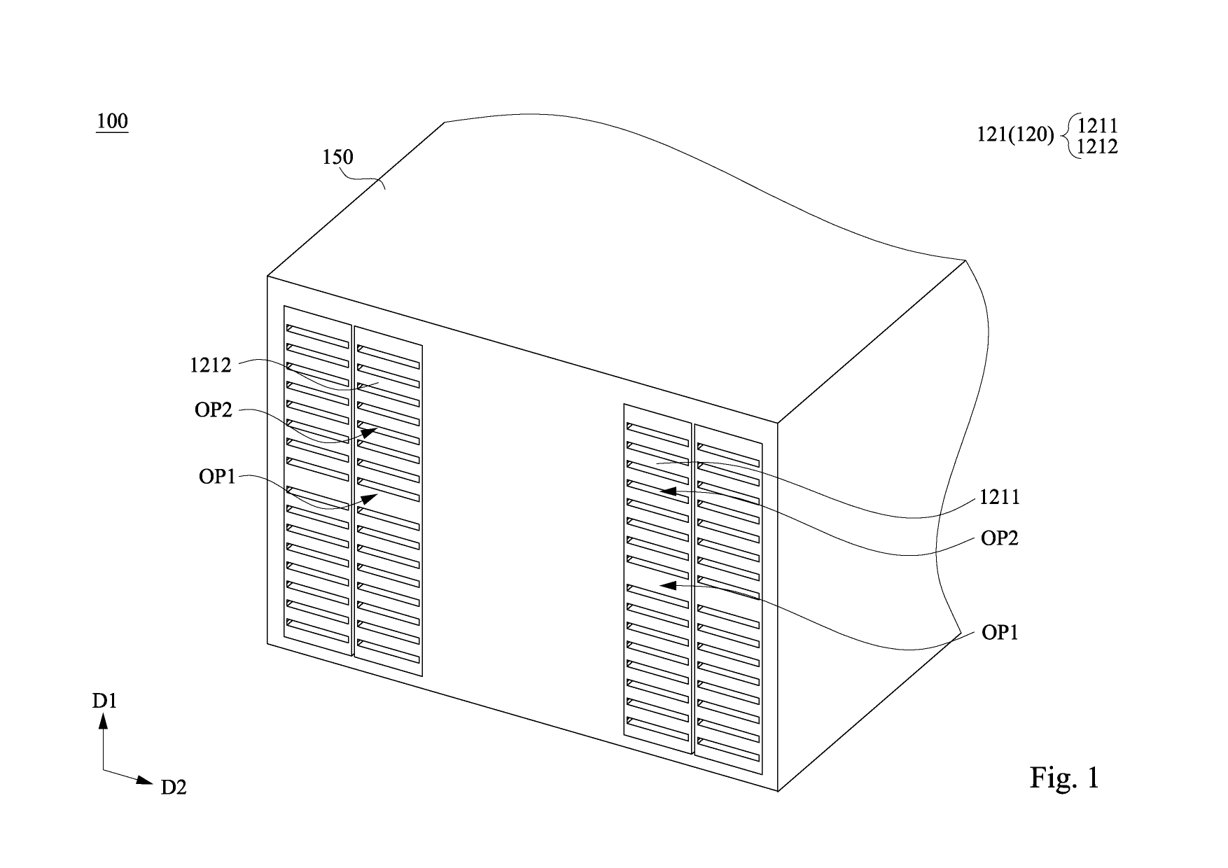

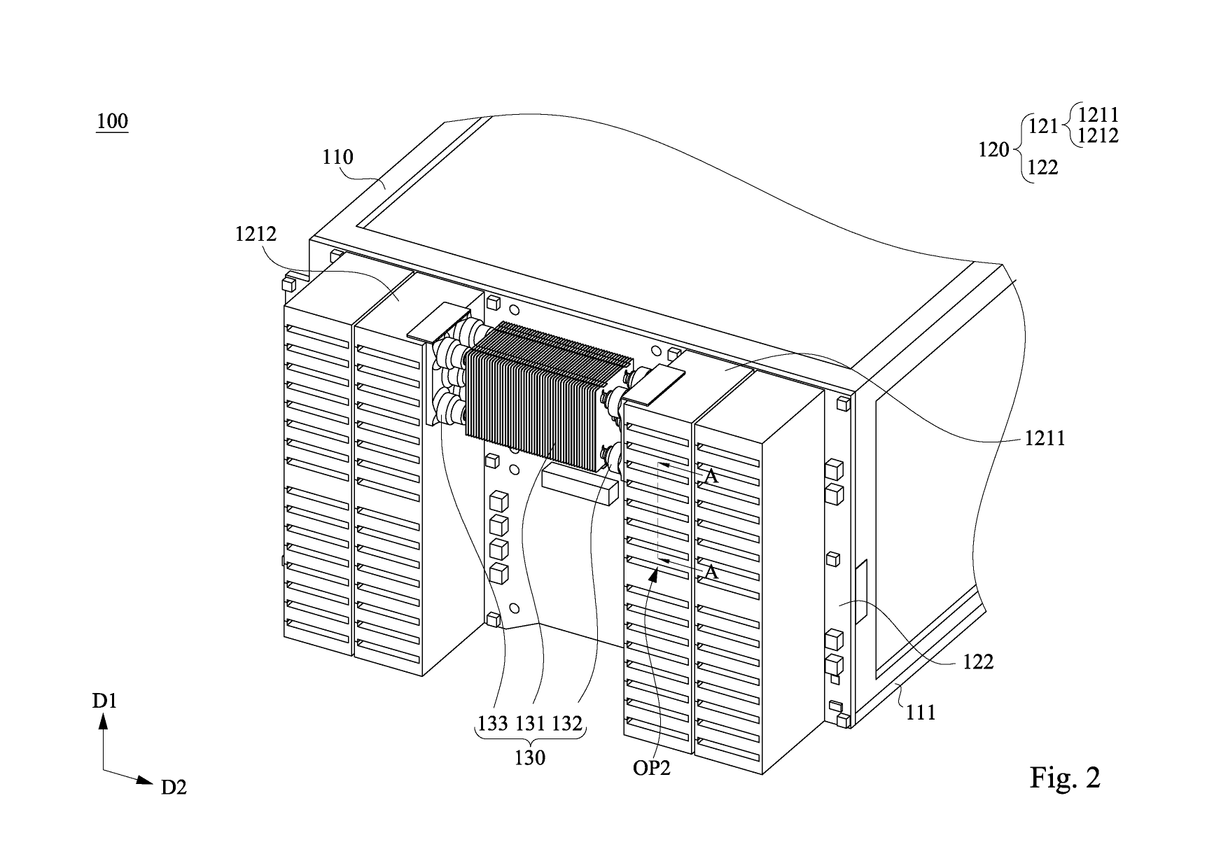

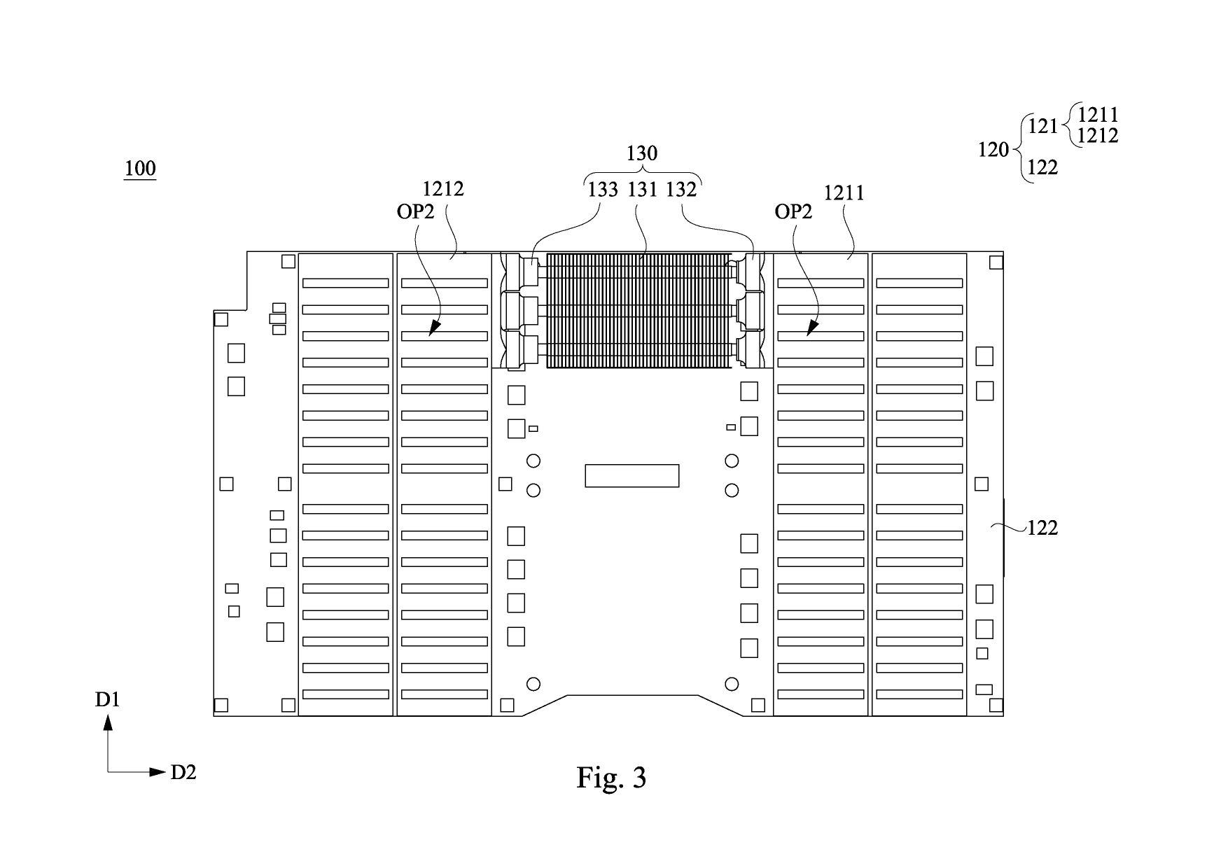

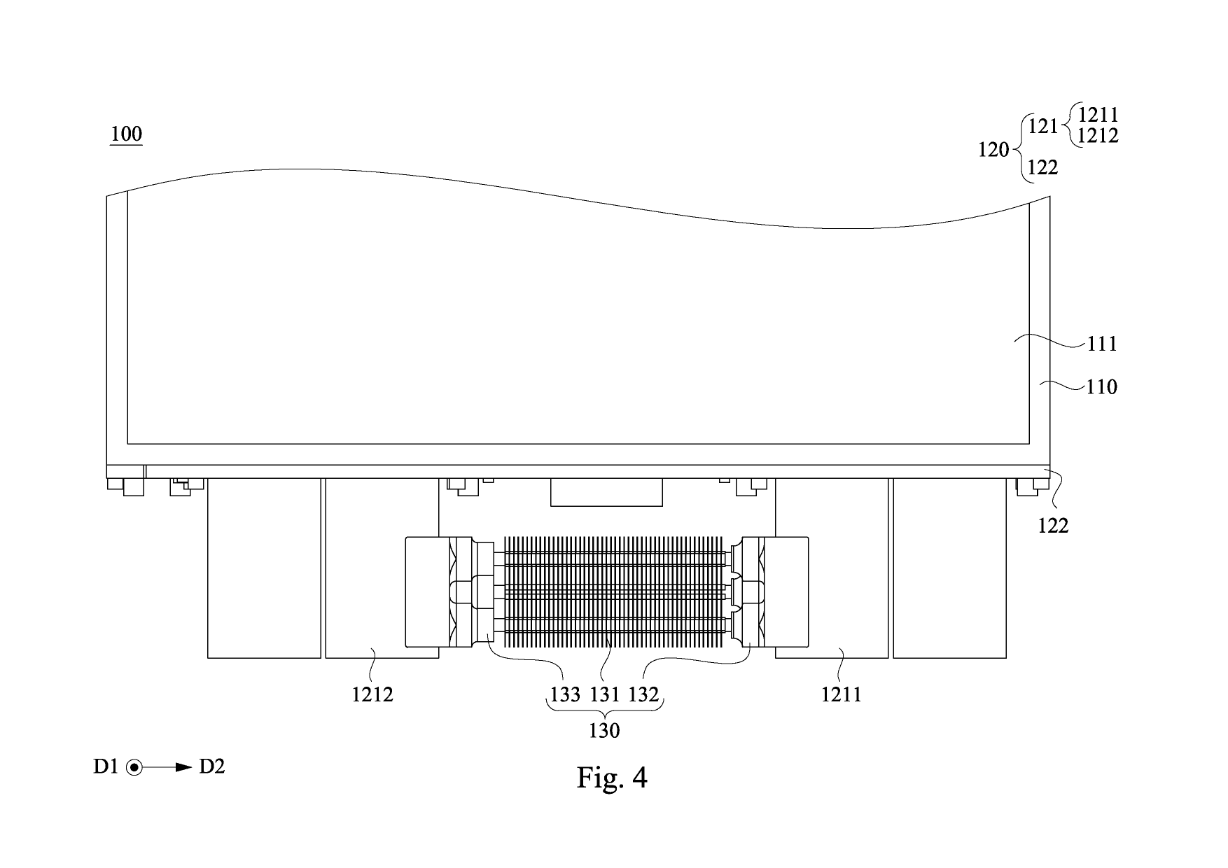

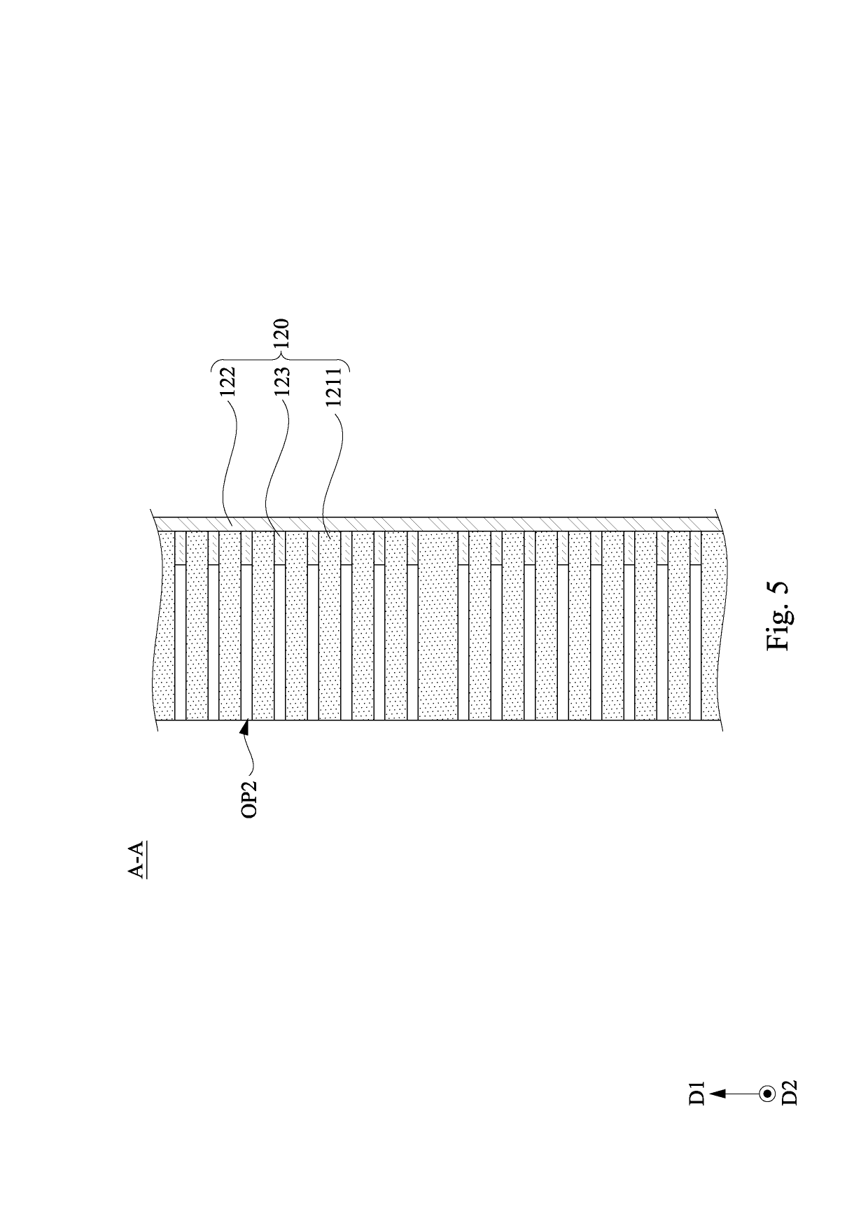

Reference is made to FIGS. 1-5. FIGS. 1-2 are schematic views of a network switch 100 according to an embodiment of the present disclosure, in which the housing 150 is omitted in FIG. 2. FIG. 3 is a front view of the network switch 100 of FIG. 2. FIG. 4 is a top view of the network switch 100 of FIG. 2. FIG. 5 is a partial sectional view along the sectional line A-A of FIG. 2. In this embodiment, as shown in FIGS. 1-5, a network switch 100 includes a machine body 110, a line card 120, a heat sink module 130 and a housing 150, in which the machine body 110, the line card 120 and the heat sink module 130 are at least partially located inside the housing 150. The housing 150 includes a plurality of openings OP1, which at least partially expose the line card 120. In practice, the line card 120 is a vertical line card (VLC). Specifically, the machine body 110 includes a main board 111. The main board 111 is disposed at a bottom of the machine body 110 and communicates with the line card 120. In practice, the main board 111 is used to process the data transmitted by the line card 120 and to manage or control the network switch 100. The line card 120 includes a printed circuit board 122, a slot structure 121, and a plurality of connectors 123. The printed circuit board 122 is disposed on the machine body 110. The printed circuit board 122 is perpendicular to the main board 111 and parallel with a first direction D1. In practice, the first direction D1 is a vertical direction, meaning that the printed circuit board 122 is vertically disposed. The slot structure 121 includes a first subsidiary slot structure 1211 and a second subsidiary slot structure 1212. According to the actual situation, the slot structure 121 is integrally formed of or combined from the first subsidiary slot structure 1211 and the second subsidiary slot structure 1212, while the first subsidiary slot structure 1211 and the second subsidiary slot structure 1212 are respectively connected with a side of the printed circuit board 122 away from the machine body 110. The first subsidiary slot structure 1211 and the second subsidiary slot structure 1212 are at least partially exposed from the opening OP1 of the housing 150. Moreover, the first subsidiary slot structure 1211 and the second subsidiary slot structure 1212 respectively have a plurality of openings OP2. The openings OP2 are located on a side of each of the first subsidiary slot structure 1211 and the second subsidiary slot structure 1212 away from the machine body 110 and exposed from the openings OP1 of the housing 150. For example, the openings OP2 of the first subsidiary slot structure 1211 and the second subsidiary slot structure 1212 are respectively arranged along the first direction D1. The connectors 123 are disposed on the printed circuit board 122 and aligned with the openings OP2 of the first subsidiary slot structure 1211 and the second subsidiary slot structure 1212. Therefore, an electronic device (not shown), such as an optical fiber transceiver, can be horizontally inserted through one of the openings OP2 and at least partially accommodated in the first subsidiary slot structure 1211 or the second subsidiary slot structure 1212. As shown in FIG. 5, the first subsidiary slot structure 1211 is illustrated as an example. Moreover the heat sink module 130 has elasticity along a second direction D2 perpendicular to the first direction D1. The heat sink module 130 is sandwiched between the first subsidiary slot structure 1211 and the second subsidiary slot structure 1212 along the second direction D2.

In other words, the heat sink module 130 is supported elastically between the first subsidiary slot structure 1211 and the second subsidiary slot structure 1212. In this way, the first subsidiary slot structure 1211 and the second subsidiary slot structure 1212 do not need additional processing to add fastening components, such as screw holes or studs, to secure the heat sink module 130. Hence, apart from a saving of labor cost, the structural strength of the line card 120 is maintained.

Moreover, since the heat sink module 130 is supported elastically between the first subsidiary slot structure 1211 and the second subsidiary slot structure 1212, even if there is a relatively large tolerance range in the distance between the first subsidiary slot structure 1211 and the second subsidiary slot structure 1212, the heat sink module 130 can still be disposed between the first subsidiary slot structure 1211 and the second subsidiary slot structure 1212 of the line card 120, which effectively enhances the application flexibility of the heat sink module 130.

Further, since the heat sink module 130 is supported elastically between the first subsidiary slot structure 1211 and the second subsidiary slot structure 1212, the installation and removal of the heat sink module 130 can be completed easily and quickly.

In practical applications, as shown in FIG. 4, the heat sink module 130 and the printed circuit board 122 are spaced apart from each other. This means the heat sink module 130 and the printed circuit board 122 do not contact with each other, such that the heat dissipation efficiency of the heat sink module 130 is enhanced.

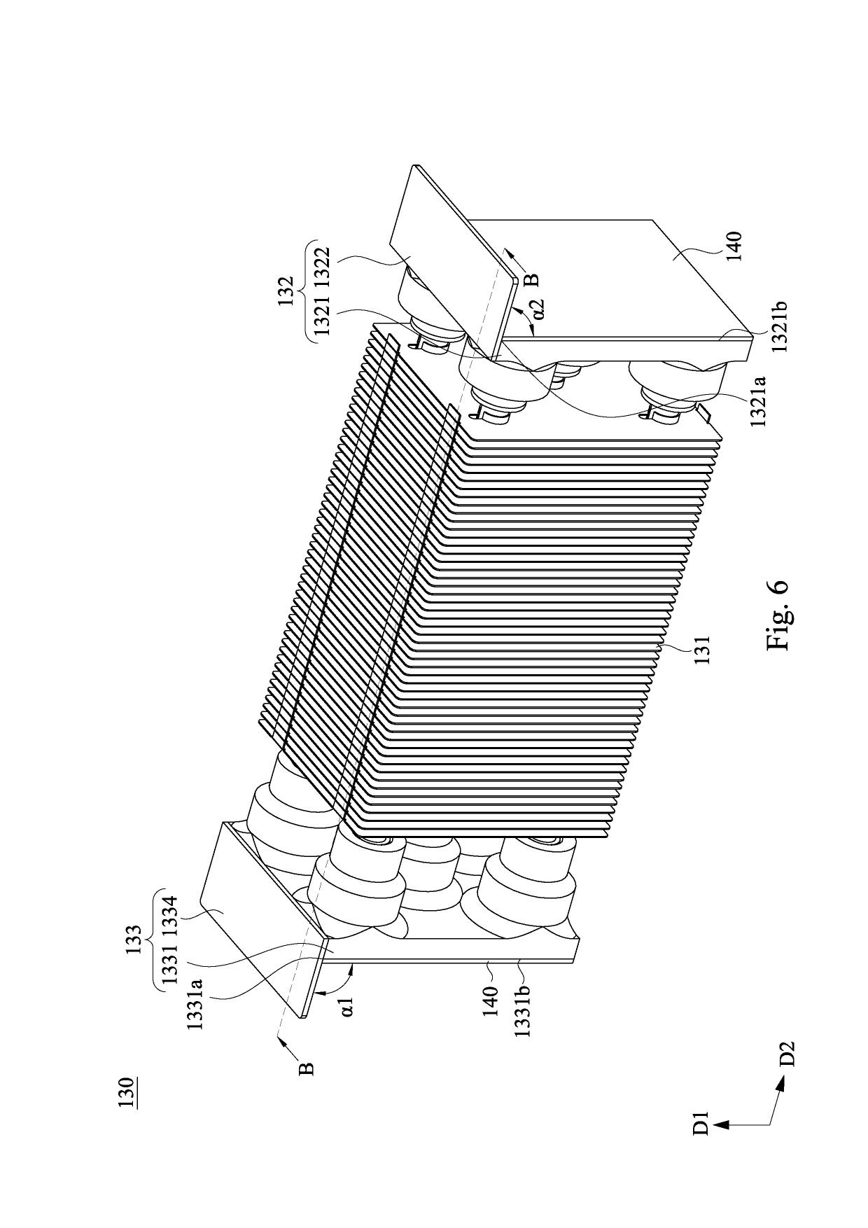

Reference is FIG. 6. FIG. 6 is a schematic view of the heat sink module 130 of FIGS. 2-4. In this embodiment, as shown in FIGS. 2-4, 6, the heat sink module 130 includes a heat dissipation body 131, a first connecting bracket 132 and a second connecting bracket 133. The first connecting bracket 132 is connected with a side of the heat dissipation body 131 along the second direction D2 and configured to abut against the first subsidiary slot structure 1211. The second connecting bracket 133 is connected with another side of the heat dissipation body 131 along the second direction D2 and configured to abut against the second subsidiary slot structure 1212. The second connecting bracket 133 has elasticity along the second direction D2, and the second connecting bracket 133 generates a force tending to elastically recover after being compressed in the second direction D2, such that the heat sink module 130 can be placed and supported between the first subsidiary slot structure 1211 and the second subsidiary slot structure 1212.

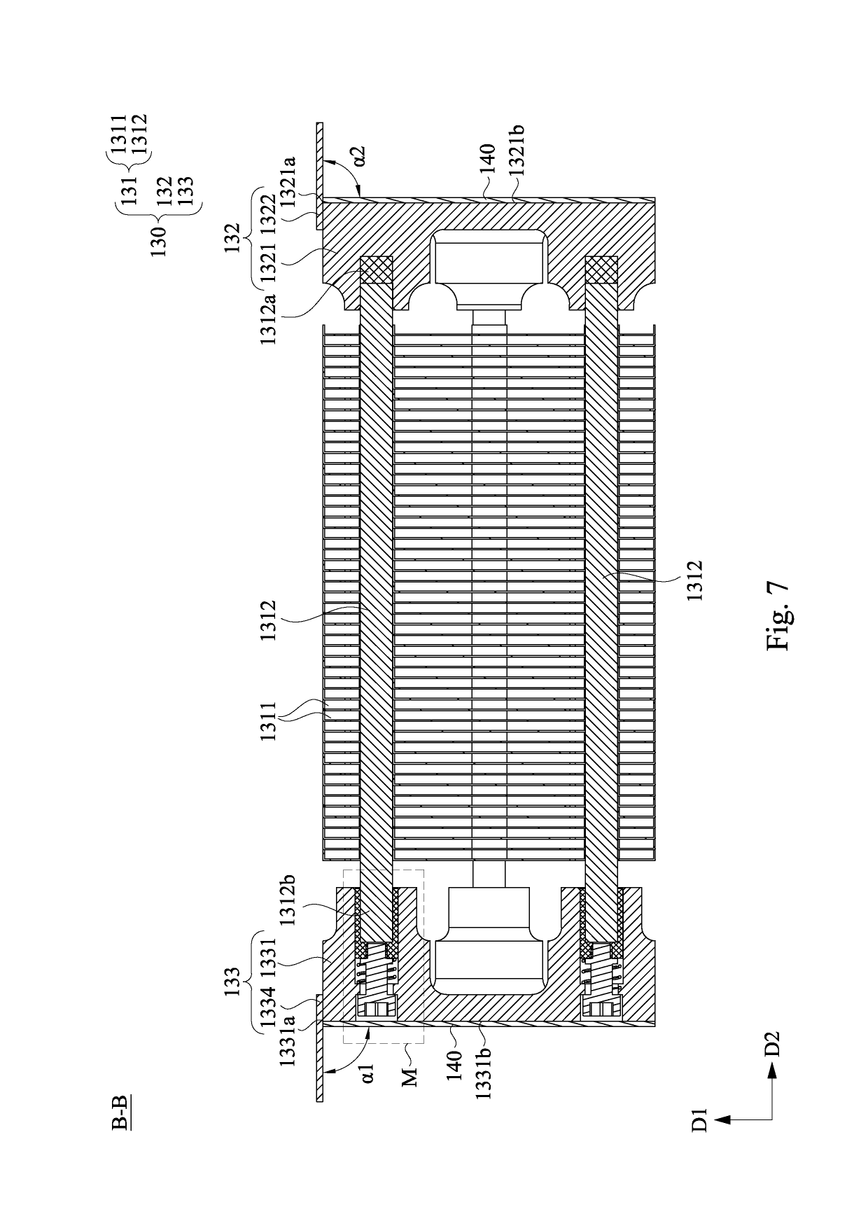

Reference is made to FIG. 7. FIG. 7 is a sectional view along the sectional line B-B of FIG. 6. In this embodiment, as shown in FIGS. 6-7, the heat dissipation body 131 includes a plurality of heat fins 1311 and a plurality of heat conducting ducts 1312. The heat fins 1311 are connected with the heat conducting ducts 1312. For example, the heat fins 1311 are stacked along the second direction D2, while the heat conducting ducts 1312 respectively extend along the second direction D2 and penetrate through the heat fins 1311. Each of the heat conducting ducts 1312 has a first end 1312a and a second end 1312b opposite to the first end 1312a. The first end 1312a is connected with the first connecting bracket 132, while the second end 1312b is connected with the second connecting bracket 133.

Furthermore, as shown in FIGS. 6-7, the second connecting bracket 133 further includes a first body 1331 and a first positioning portion 1334. The second end 1312b of each of the heat conducting ducts 1312 is connected with the first body 1331 of the second connecting bracket 133. The first positioning portion 1334 is connected with an edge 1331a of the first body 1331. The first positioning portion 1334 forms a first included angle α1 together with a surface 1331b of the first body 1331 away from the first connecting bracket 132. The first positioning portion 1334 is configured to abut against the second subsidiary slot structure 1212. The first connecting bracket 132 includes a second body 1321 and a second positioning portion 1322. The first end 1312a of each of the heat conducting ducts 1312 is connected with the second body 1321 of the first connecting bracket 132. The second positioning portion 1322 is connected with an edge 1321a of the second body 1321. The second positioning portion 1322 forms a second included angle α2 together with a surface 1321b of the second body 1321 away from the second connecting bracket 133. The second positioning portion 1322 is configured to abut against the first subsidiary slot structure 1211. To be specific, since the first positioning portion 1334 and the second positioning portion 1322 respectively abut against the upper surfaces of the second subsidiary slot structure 1212 and the first subsidiary slot structure 1211, the stability of the heat sink module 130 being installed on the line card 120 can be effectively improved. In practical applications, both the first included angle α1 and the second included angle α2 are right angles.

In addition, as shown in FIGS. 6-7, the network switch 100 further includes two thermal pads 140. One of the thermal pads 140 is disposed on the surface 1331b of the second connecting bracket 133 away from the first connecting bracket 132, and sandwiched between the second connecting bracket 133 and the second subsidiary slot structure 1212. Another one of the thermal pads 140 is disposed on the surface 1321b of the first connecting bracket 132 away from the second connecting bracket 133, and sandwiched between the first connecting bracket 132 and the first subsidiary slot structure 1211. Provided that the thermal pads 140 are sandwiched between the line card 120 and the heat sink module 130, the efficiency of heat transfer can be effectively enhanced.

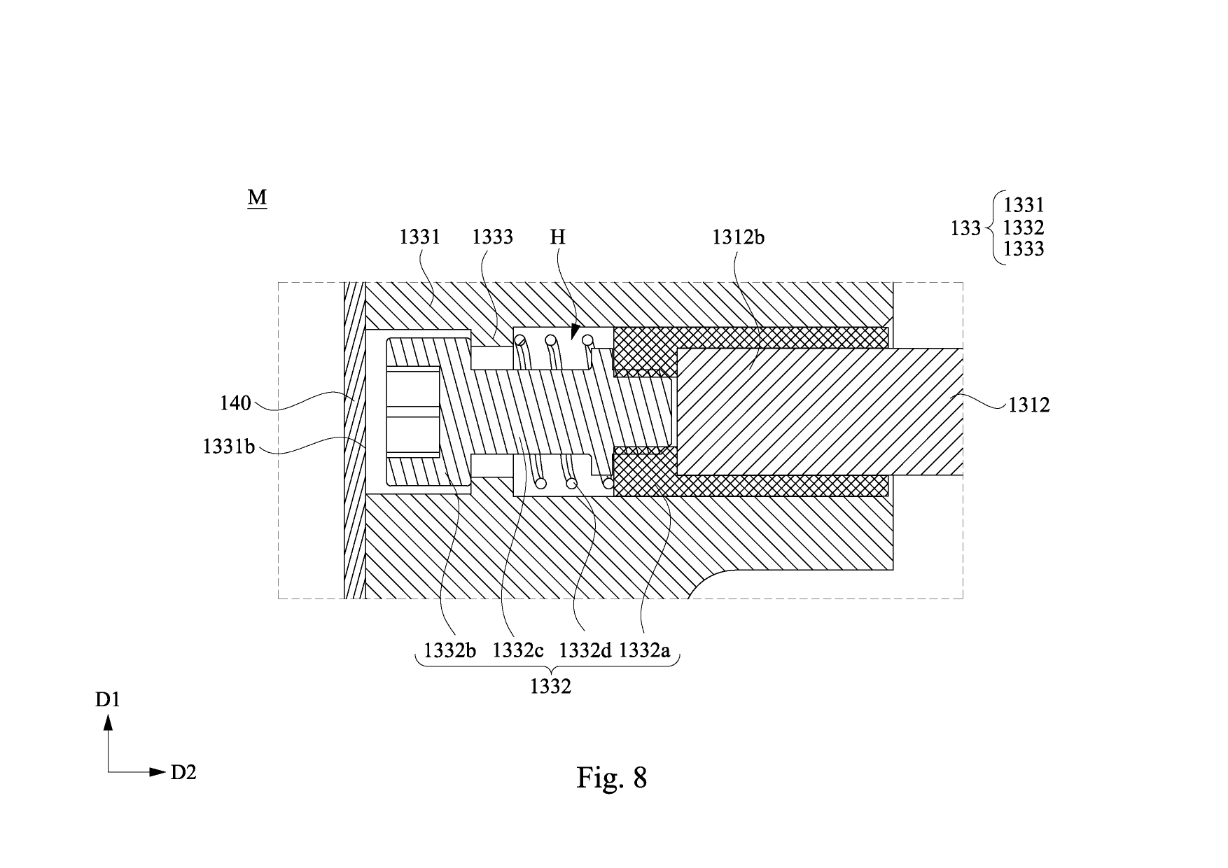

Reference is made to FIG. 8. FIG. 8 is an enlarged view of the zone M of FIG. 7. In this embodiment, the second connecting bracket 133 further includes a connecting piece 1332, while the first body 1331 has a through hole H. As shown in FIG. 8, the connecting piece 1332 is at least partially located in the through hole H and elastically connected with the first body 1331 along the second direction D2. The second end 1312b of one of the heat conducting ducts 1312 is connected with the connecting piece 1332.

To be specific, as shown in FIG. 8, the second connecting bracket 133 further includes a protruding annulus 1333. The protruding annulus 1333 is disposed on the first body 1331 and located inside the through hole H. The connecting piece 1332 further includes a sleeve 1332a, a snapping portion 1332b, a connecting portion 1332c and an elastic element 1332d. The sleeve 1332a is slidably disposed in the through hole H along the second direction D2. The sleeve 1332a accommodates the second end 1312b of one of the heat conducting ducts 1312 therein. The snapping portion 1332b is located at a side of the protruding annulus 1333 and configured to abut against the protruding annulus 1333. The connecting portion 1332c is connected between the sleeve 1332a and the snapping portion 1332b along the second direction D2. The elastic element 1332d is located at another side of the protruding annulus 1333. An end of the elastic element 1332d abuts against the protruding annulus 1333. Another end of the elastic element 1332d abuts against the sleeve 1332a. In practical applications, the elastic element 1332d can be a spring. Moreover, the snapping portion 1332b and the connecting portion 1332c can be a screw, while the sleeve 1332a can have a threaded hole for coupling with the connecting portion 1332c.

To be specific, when the second connecting bracket 133 is compressed towards the first connecting bracket 132, the first body 1331 of the second connecting bracket 133, together with the protruding annulus 1333, moves towards the sleeve 1332a. That is, the sleeve 1332a slides towards the protruding annulus 1333 in the through hole H of the first body 1331, causing the elastic element 1332d to be compressed between the protruding annulus 1333 and the sleeve 1332a to generate a certain magnitude of elastic force. This causes the first body 1331, together with the protruding annulus 1333, to tend to elastically move away from the first connecting bracket 132 along the second direction D2, thereby forming an elastic force which supports the heat sink module 130 between the first subsidiary slot structure 1211 and the second subsidiary slot structure 1212. In practical applications, to facilitate the sliding of the sleeve 1332a within the through hole H of the first body 1331, a thermal paste can be applied between the sleeve 1332a and the first body 1331.

In conclusion, the aforementioned embodiments of the present disclosure have at least the following advantages:

(1) Since the heat sink module is supported elastically between the subsidiary slot structures, no additional processing is needed to add fastening components to secure the heat sink module. Hence, apart from a saving of labor cost, the structural strength of the line card is maintained.

(2) Since the heat sink module is supported elastically between the subsidiary slot structures, even if there is a relatively large tolerance range in the distance between the subsidiary slot structures, the heat sink module can still be disposed between the subsidiary slot structures of the line card, which effectively enhances the application flexibility of the heat sink module.

(3) Since the heat sink module is supported elastically between the subsidiary slot structures, the installation and removal of the heat sink module can be completed easily and quickly.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A heat sink module, comprising:
a first connecting bracket;
a second connecting bracket having at least partial elasticity along a direction; and
a heat dissipation body, an end of the heat dissipation body being connected with the first connecting bracket along the direction and another end of the heat dissipation body being connected with the second connecting bracket along the direction.

2. The heat sink module of claim 1, wherein the heat dissipation body comprises at least one heat conducting duct having a first end and a second end opposite to the first end, the second connecting bracket comprises:
a first body having at least one through hole; and
at least one connecting piece located in the through hole and elastically connected with the first body along the direction, the connecting piece is connected with the second end.

3. The heat sink module of claim 2, wherein the second connecting bracket further comprises a protruding annulus disposed inside the through hole, the connecting piece further comprises:
a sleeve slidably disposed in the through hole along the direction, the sleeve accommodates the second end;
a snapping portion configured to abut against the protruding annulus;
a connecting portion connected between the sleeve and the snapping portion along the direction; and
an elastic element, an end of the elastic element abuts against the protruding annulus, another end of the elastic element abuts against the sleeve.

4. The heat sink module of claim 3, wherein the sleeve and the snapping portion are located at opposite sides of the protruding annulus.

5. The heat sink module of claim 2, wherein the second connecting bracket further comprises:
a first positioning portion connected with an edge of the first body and forming a first included angle together with a surface of the first body away from the first connecting bracket,
the first connecting bracket comprises:
a second body configured to connect with the first end; and
a second positioning portion connected with an edge of the second body and forming a second included angle together with a surface of the second body away from the second connecting bracket.

6. The heat sink module of claim 5, wherein the first included angle and the second included angle are respectively a right angle.

7. A network switch, comprising:
a machine body comprising a main board disposed at a bottom of the machine body;
a line card comprising:
a printed circuit board disposed on the machine body and being perpendicular to the main board;
a slot structure comprising a first subsidiary slot structure and a second subsidiary slot structure respectively connected with the printed circuit board, the first subsidiary slot structure and the second subsidiary slot structure respectively having a plurality of openings; and
a plurality of connectors disposed on the printed circuit board and aligned with the openings; and
a heat sink module sandwiched between the first subsidiary slot structure and the second subsidiary slot structure along a direction, the heat sink module comprising:
a heat dissipation body;
a first connecting bracket connected with a side of the heat dissipation body along the direction and configured to abut against the first subsidiary slot structure; and
a second connecting bracket connected with another side of the heat dissipation body along the direction and configured to abut against the second subsidiary slot structure, the second connecting bracket has elasticity along the direction.

8. The network switch of claim 7, wherein the heat dissipation body comprises at least one heat conducting duct having a first end and a second end opposite to the first end, the second connecting bracket comprises:
a first body having at least one through hole; and
at least one connecting piece located in the through hole and elastically connected with the first body along the direction, the connecting piece is connected with the second end.

9. The network switch of claim 8, wherein the second connecting bracket further comprises a protruding annulus disposed inside the through hole, the connecting piece further comprises:
a sleeve slidably disposed in the through hole along the direction, the sleeve accommodates the second end;
a snapping portion configured to abut against the protruding annulus;
a connecting portion connected between the sleeve and the snapping portion along the direction; and
an elastic element, an end of the elastic element abuts against the protruding annulus, another end of the elastic element abuts against the sleeve.

10. The network switch of claim 9, wherein the sleeve and the snapping portion are located at opposite sides of the protruding annulus.

11. The network switch of claim 8, wherein the second connecting bracket further comprises:
a first positioning portion connected with an edge of the first body and forming a first included angle together with a surface of the first body away from the first connecting bracket, the first positioning portion is configured to abut against the second subsidiary slot structure,
the first connecting bracket comprises:
a second body configured to connect with the first end; and
a second positioning portion connected with an edge of the second body and forming a second included angle together with a surface of the second body away from the second connecting bracket, the second positioning portion is configured to abut against the first subsidiary slot structure.

12. The network switch of claim 11, wherein the first included angle and the second included angle are respectively a right angle.

13. The network switch of claim 7, wherein the first subsidiary slot structure and the second subsidiary slot structure are integrally formed.

14. The network switch of claim 7, wherein the heat sink module exerts an elastic force against the first subsidiary slot structure and the second subsidiary slot structure along the direction.

15. The network switch of claim 7, wherein the heat sink module and the printed circuit board are spaced apart from each other.

16. The network switch of claim 7, further comprising:
at least one thermal pad sandwiched between the heat sink module and one of the first subsidiary slot structure and the second subsidiary slot structure.
